(19) United States
(12) Patent Application Publication
(10) Pub. No.: US 2010/0224988 A1
(43) Pub. Date: Sep. 9, 2010

(54) SEMICONDUCTOR PACKAGE SUBSTRATE, SEMICONDUCTOR PACKAGE USING THE SUBSTRATE, AND METHOD OF MANUFACTURING SEMICONDUCTOR PACKAGE SUBSTRATE

(75) Inventors: Koji HOSOKAWA, Tokyo (JP); Atsushi Tomohiro, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/716,664

(22) Filed: Mar. 3, 2010

(30) Foreign Application Priority Data
Mar. 6, 2009 (JP) 2009-053361

(51) Int. Cl. H01L 23/488

(52) U.S. Cl. 257/693; 257/E23.023; 257/E23.069

(57) ABSTRACT

A semiconductor package substrate comprises a substrate core layer, and a land formed on one surface of the substrate core layer for mounting an external electrode terminal thereon. Then, a hole having a diameter smaller than that of the land is dug into the substrate core layer from a position in contact with the land, and the hole is filled with a low modulus resin exhibiting a modulus of elasticity lower than that of a material of the substrate core layer. In this way, the present invention accomplishes a reduction in size of a semiconductor package and improved electrical resistance of a semiconductor package during board level thermal cycle testing.

This application is based upon and claims the benefit of priority from Japanese patent application No. 2009-053361, filed on Mar. 6, 2009, the disclosure of which are incorporated herein in its entirety by reference.

### BACKGROUND OF THE INVENTION

1. Field of the Invention

The present invention relates to a semiconductor package such as a BGA package, a semiconductor package substrate for use in the manufacturing the semiconductor package, and a method of manufacturing the same.

2. Description of Related Art

In recent years, BGA (Ball Grid Array) and LGA (Land Grid Array) type packages have become pervasive in order to respond to requirements for a reduction in size and thickness of semiconductor packages, and an increasingly higher need is recently envisaged for a further reduction in thickness.

FIG. 1 shows the structure of a general BGA type semiconductor package. In a semiconductor package as shown in FIG. 1, a reduction in size of the semiconductor package is accompanied with increasingly greater reduction in size of solder balls, which serve as external electrode terminals, and lands, which serve as mounts for the solder balls, together with increasingly narrower land pitches. This results in a problem of lower electrical residence during board level thermal cycle testing, leading to a need for taking measures for alleviating stresses in order to improve the resistance.

In this regard, the board level temperature cycle resistance refers to the abilities of components, wires, electric connections and the like, which make up a semiconductor package, to withstand temperature variations or repetitions thereof when the semiconductor package is mounted on an external printed board and undergoes a temperature cycle test in this state.

Patent Document 1 (Japanese Patent Laid-Open No. 02-042738A) and Patent Document 2 (Japanese Patent Laid-Open No. 02-042739A) disclose techniques for forming lands on a flexible adhesive layer disposed on an external printed board on which a BGA type semiconductor package is mounted. Also, Patent Document 3 (Japanese Patent Laid-Open No. 2002-289741A) and Patent Document 4 (Japanese Patent Laid-Open No. 2003-133478A) disclose techniques for providing a buffer material on a package substrate which forms part of a BGA package. Other similar related art includes structures disclosed in Patent Document 5 (Japanese Patent Laid-Open No. 2007-073681A) and Patent Document 6 (Japanese Patent Laid-Open No. 11-354669A).

The structures disclosed in Patent Documents 1-6 can certainly improve electrical resistance of BGA packages and the like during board level thermal cycle testing of a semiconductor package. However, the structures in the documents 1-6 require a flexible adhesive layer or a buffer material as one layer separate from a package substrate.

For developing a stress alleviation effect required to improve the board level temperature cycle resistance, a stress alleviation layer must be made to have a thickness in a range of several tens of micrometers (μm) to several hundreds of micrometers (μm). The requirement for such a thickness is a inevitable problem for recent BGA type packages which target such a reduction in thickness for reducing the thickness of a package substrate to less than 500 μm.

In addition, if an overall package substrate is created as a single layer of buffer material, the resulting substrate will include flexible sites which should essentially ensure the rigidity. Consequently, other problems will arise such as wire breaks and through vias formed, for example, of Au or Cu, lower accuracy of positioning wires to a substrate, and resulting difficulties in manufacturing.

### SUMMARY

In one embodiment, the present invention provides a semiconductor package substrate as follows. Specifically, the substrate comprises a substrate core layer, and a land formed on one surface of the substrate core layer for mounting an external electrode terminal thereon. Then, a low modulus resin, exhibiting a modulus of elasticity lower than that of the material of the substrate core layer, is filled in a hole dug into the substrate core layer from a position in contact with the land.

In another embodiment, the present invention provides a method of manufacturing the semiconductor package substrate according to the foregoing aspect. The method comprises the steps of providing the substrate core layer, digging a hole into the substrate core layer from a position at which the land is disposed, filling the hole with a low modulus resin, the modulus of elasticity of which is lower than that of a material of the substrate core layer, disposing a wiring layer on the surface of the substrate core layer in which the low modulus resin has been filled, and patterning the wiring layer in a predetermined manner to form the land at a position corresponding to the hole filled with the low modulus resin.

The electrical resistance of a semiconductor package that uses the substrate of the foregoing aspect can be improved during a board level thermal cycle test of the package because the influence of stresses acting on the lands and external electrode terminals is alleviated during a board level temperature cycle testing of the semiconductor package. Also, since the low modulus resin is filled only in the hole dug into the substrate core layer, the thickness of the package substrate does not increase, thus achieving a reduction in size and thickness of the semiconductor package.

Consequently, the present invention can accomplish both of a reduction in size and an improved resistance during board level thermal cycle testing of a semiconductor package.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a diagram showing the structure of a general BGA type semiconductor package;

FIG. 2 is a diagram showing the structure of a semiconductor package according to one embodiment of the present invention;

FIG. 3 is an enlarged view around a land in one embodiment of the present invention;

FIG. 4 is a plan view of a package substrate in FIG. 3, viewed through from an external electrode terminal side; and

FIGS. 5(a)-5(g) are cross-sectional views showing steps of manufacturing a semiconductor package according to one embodiment of the present invention.

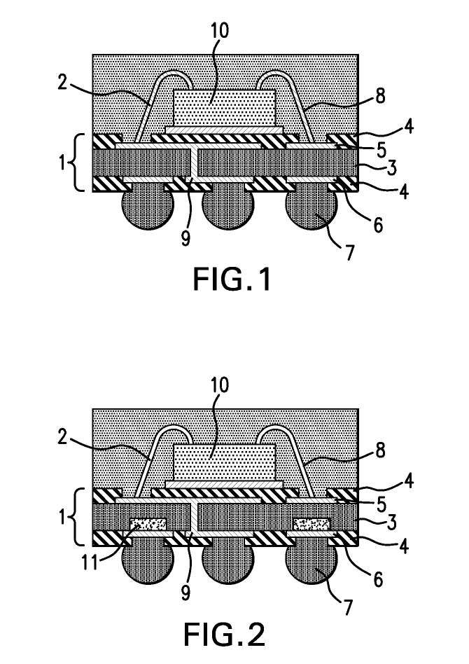

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Referring to FIG. 2, a semiconductor package comprises package substrate 1 made, for example, of a glass epoxy material, like general BGA packages, and substantially in a rectangular shape, as viewed in plane.

Chip (semiconductor circuit element) 10 is fixed on one surface of package substrate 1 through an insulating adhesive. Electrode pads of chip 10 and bonding pads of package substrate 1 are interconnected through conductive bonding wires 8 made, for example, of gold or copper. Surroundings of chip 10 and bonding wires 8 are covered with sealing resin 2 made, for example, of a thermosetting resin such as epoxy resin.

Lands 6 are formed on the other surface of package substrate 1, and land 6 is formed, for example, of a solder ball, which serves as external electrode terminal 7. The semiconductor package is mounted on an external printed board using the solder balls.

Package substrate 1 comprises substrate core layer 3, wires 5, vias 9, and protective layer 4. Wires 5 and vias 9 are formed through predetermined patterning such that chip 10 is electrically connected to external electrode terminals 7. Protective layer 4 is coated on a surface area of package substrate 1 except for bonding pads and lands 6 to protect the wires.

In this embodiment, holes are dug into regions of substrate core layer 3 on the opposite side to external electrode terminals 7 from positions in contact with lands 6 for filling a low modulus resin therein. The holes are filled with low modulus resin 11 such as epoxy resin and silicone resin, by way of example. The semiconductor package of this embodiment is bonded on an external printed board, not shown, through external electrode terminals 7 with solder. When the semiconductor package undergoes a temperature cycle test in this state, stress acting on external electrode terminal 7 is alleviated by low modulus resin 11. Accordingly, the present invention can improve the reliability of products.

The holes for filling a low modulus resin may extend through substrate core layer 3, or alternatively, the low modulus resin may not be filled in part or any of the holes in order to leave hollow spaces therein.

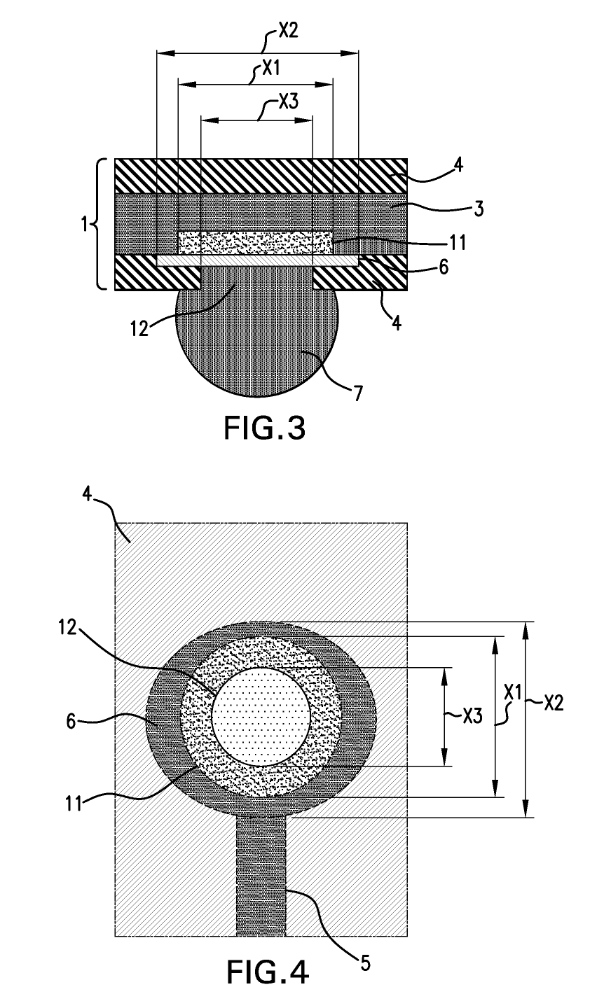

FIG. 3 shows an enlarged view of surroundings of a land, and FIG. 4 is a plan view showing the structure of FIG. 3 seen through the substrate from the side on which the external electrode terminal is disposed, where reference X1 represents the diameter of low modulus resin filling hole 14; reference X2, the diameter of land 6; and reference X3, the diameter of protective layer opening 12. In this embodiment, a round hole for filling a low modulus resin is preferably formed to have diameter X1 smaller than diameter X2 of the round land, and diameter X3 of protective layer opening smaller than diameter X1 of the round land, as shown in these figures. By forming the hole with this dimension, the land can be readily formed on the hole for filling a low modulus resin in substrate wire patterning, in addition to a stress alleviating effect provided in a board level thermal cycling test, and the hole for filling a low modulus resin can be closed by the land to prevent the hole from being exposed, and the land can be closed by the protective layer from peeling of land.

Substrate core layer 3 is made of a general substrate core material which is made by impregnating glass cloth, for example, with a resin such as epoxy resin, cyanate resin or the like, and exhibits a modulus of elasticity of several tens of GPa. Substrate core layer 3 having such a high rigidity is susceptible to peeling of lands and solder balls as well as to cracking of the substrate due to stress acting on the solder balls and lands, which are not alleviated when the semiconductor package is mounted on an external printed board.

In this embodiment, accordingly, low modulus resin 11 is filled in part of substrate core layer 2 beneath land 6. Low modulus resin 11 is epoxy resin, silicone resin or the like, the modulus whose elasticity is approximately in a range of several hundreds of MPa to several GPa, and whose elasticity is sufficiently lower than the modulus of elasticity of substrate core layer 3. Such low modulus resin 11, when present beneath land 6, can alleviate stress acting on land 6, thus improving the electrical resistance of a semiconductor package during board level thermal cycle testing.

Next, a description will be given of a method of manufacturing the semiconductor package according to this embodiment.

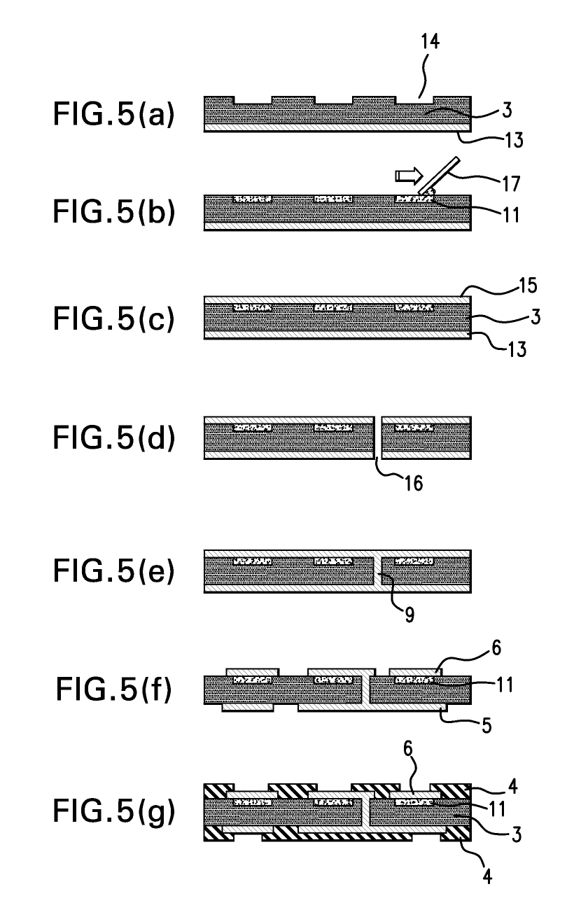

FIGS. 5(a)-5(g) show steps of manufacturing package substrate 1 which constitutes a main component of the semiconductor package of the present invention.

First, as shown in FIG. 5(a), wiring layer 13 made, for example, of copper foil or the like has been adhered on one surface of substrate core layer 3 (on which chip 10 is mounted), made of a glass epoxy material. Also, hole 14 having a diameter smaller than that of land 6 is formed at a position, at which land 6 is disposed, on the other surface of substrate core layer 3 (on which external electrode terminal 7 is attached). Hole 14 is filled with low modulus resin 11 at a later time.

Next, as shown in FIG. 5(b), hole 14 is filled with low modulus resin 11, for example, epoxy resin, silicone resin or the like by a printing method. A surplus resin overflowing from hole 14 is scraped off by squeegee 17 to make low modulus resin 11 even on the surface of substrate core layer 3. Subsequently, heat treatment is performed to complete the filling of low modulus resin 11.

Further, as shown in FIG. 5(c), wiring layer 15 made, for example, of copper foil or the like is adhered on the surface of substrate core layer 3 on which low modulus resin 11 has been filled.

Each subsequent step is a general step involved in the manufacturing of BGA package substrates.

Briefly described, via hole 16 is formed through substrate core layer 3 which has wiring layers 13, 15 formed on both surfaces thereof, as shown in FIG. 5(d), and via 9 formed by a plating method to make an electric connection between wiring layers 13, 15, as shown in FIG. 5(e).

Further, wiring layers 13, 15 are respectively patterned in a predetermined manner by photolithography to form wires 5 and lands 6, as shown in FIG. 5(f). Each land 6 is in contact with low modulus resin 11.

Finally, substrate core layer 3 is coated with a solder resist, which serves as protective layer 4, on the front and back surfaces, and the solder resist is patterned in a predetermined manner to complete package substrate 1, as shown in FIG. 5(g). A wiring area not coated with protective layer 4 serves as bonding stitches and solder ball mounts.

According to the semiconductor package as described above, the following advantages are provided.

The present invention provides a structure where hole 14 having a diameter smaller than that of land 6 is dug into substrate core layer 3 from a position in contact with land 6, and this hole is filled with low modulus resin 11 which exhibits a modulus of elasticity lower than that of the material of substrate core layer 3. Such a structure can alleviate stress acting on land 6 and external electrode terminal 7 during board level thermal cycle testing of the semiconductor package, thus improving the electrical resistance of a semiconductor package during board level thermal cycle testing.

Also, since low modulus resin 11 is filled only in holes 14 dug into substrate core layer 3 in the foregoing structure, the thickness of the package substrate does not increase, so that the semiconductor package can be reduced in thickness. Further, according to this structure, wires 5, through vias 9 and the like will not suffer from breaks because the overall substrate can ensure sufficient rigidity.

While the semiconductor package of the present invention has been described with reference to one embodiment thereof, the present invention encompasses various modifications added to the foregoing embodiment within the scope of the technical idea of the present application.

For example, hole 14 filled with low modulus resin 11 may extend through substrate core layer 3 from the surface on which land 6 is formed to the surface on which chip 10 is mounted. Alternatively, hole 14 may not be completely filled with low modulus resin 11, but part or all of hole 14 may remain hollow.

Although the inventions has been described above in connection with several preferred embodiments thereof, it will be appreciated by those skilled in the art that those embodiments are provided solely for illustrating the invention, and should not be relied upon to construe the appended claims in a limiting sense.

In addition, while not specifically claimed in the claim section, the applicant reserves the right to include in the claim section of the application at any appropriate time the following methods:

AA. A method of manufacturing a semiconductor package substrate comprising a substrate core layer, a land formed on one surface of said substrate core layer for mounting an external electrode terminal thereon, and a low modulus resin exhibiting a modulus of elasticity lower than that of a material of said substrate core layer, said resin being filled in a hole dug into said substrate core layer from a position in contact with said land, said method comprising the steps of:

providing said substrate core layer;

digging a hole into said substrate core layer from a position at which said land is disposed;

filling said hole with a low modulus resin which exhibits a modulus of elasticity lower than that of a material of said substrate core layer;

disposing a wiring layer on the surface of said substrate core layer in which said low modulus resin has been filled; and

patterning said wiring layer in a predetermined manner to form said land at a position corresponding to said hole filled with said low modulus resin.

AA1. The method of manufacturing a semiconductor package substrate above AA, wherein said land is formed to be larger than an opening of said hole.
AA2. The method of manufacturing a semiconductor package substrate above AA, wherein said hole is partially or completely filled with said low modulus resin.

What is claimed is:

1. A semiconductor device with a package substrate, the package substrate comprising:
a substrate core layer;
a land formed on one surface of said substrate core layer for mounting an external electrode terminal thereon; and
a low modulus resin exhibiting a modulus of elasticity lower than that of a material of said substrate core layer, said resin being filled in a hole dug into said substrate core layer from a position in contact with said land.

2. The device according to claim 1, wherein said hole is closed by said land.

3. The device according to claim 1, wherein said hole filled with said low modulus resin extends through said substrate core layer.

4. The device according to claim 1, wherein said hole is completely filled with said low modulus resin.

5. The device according to claim 1, wherein said hole is filled with said low modulus resin such that said hole partially remains hollow.

6. The device according to claim 1, wherein said substrate core layer exhibits a modulus of elasticity of several tens of GPa, and said low modulus resin exhibits a modulus of elasticity in a range of several hundreds of MPa to several GPa.

7. A semiconductor device comprising a package substrate, the package substrate comprising:
a substrate core layer;
a round land formed on one surface of said substrate core layer for mounting an external electrode terminal thereon; and
a round hole dug into said substrate core layer from a position in contact with said round land; and
a low modulus resin exhibiting a modulus of elasticity lower than that of a material of said substrate core layer, being filled in said round hole; and
a protective layer on one surface of said substrate core layer, which opened round protective layer opening on said round land for mounting an external electrode terminal.

8. The device according to claim 7, wherein circumference of said round land is covered by said protective layer.

9. The device according to claim 7, wherein said round hole is closed by said round land.

10. The device according to claim 7, wherein diameter of said round protective layer opening is smaller than diameter of said round land.

11. The device according to claim 7, wherein diameter of said round protective layer opening is smaller than diameter of said round hole.

12. A semiconductor device comprising:
an insulating core substrate having first and second main surfaces opposite to each other;
at least one low-modulus resin layer selectively embedded in the insulating core substrate on a side of the first main surface thereof;
at least one conductive land formed on the low-modulus resin layer;
a semiconductor chip mounted on the insulating core substrate on a side of the second main surface thereof and having at least one electrode; and
at least one conductive layer formed to electrically connect the electrode of the semiconductor chip to the conductive land.

13. The device according to claim 12, wherein the low-modulus resin having a top surface, on which the conductive land is formed, is substantially coplanar with the first main surface of the insulating core substrate.

14. The device according to claim 12, wherein the low-modulus resin is smaller in area than the conductive land so that the low-modulus resin is substantially hidden by the conductive land.

15. The device according to claim 14, further comprising and insulating protective film covering the first main surface of the insulating core substrate and the conductive land, the insulating protective film having at least one aperture that exposes a part of the conductive land.

16. The device according to claim 15, wherein the aperture is smaller in area than the low-modulus resin.

17. The device according to claim 12, wherein the conductive layer comprises a first portion embedded into the insulating core substrate and a second portion intervening between the first portion and the conductive land.

18. The device according to claim 17, wherein the conductive layer further comprises a third portion elongated from the first portion over the second surface of the insulating core substrate and a wire connecting the electrode of the semiconductor chip to the third portion.
